(19) United States
(12) Patent Application Publication
(10) Pub. No.: US 2018/0212556 A1
(43) Pub. Date: Jul. 26, 2018

(54) SOLAR MODULE

(71) Applicant: HANWHA Q CELLS GMBH, Bitterfeld-Wolfen (DE)

(72) Inventors: Frank WEGERT, Holzweissig (DE); Dirk SACHSE, Leipzig (DE); Henning BUSSE, Leipzig (DE)

(21) Appl. No.: 15/742,007

(22) PCT Filed: May 27, 2016
(86) PCT No.: PCT/DE2016/100245

§ 371 Date: Jan. 4, 2018

(30) Foreign Application Priority Data
Jul. 6, 2015 (DE) 10 2015 110 908.5

(51) Int. Cl. H02S 30/10; H01L 31/048

(52) U.S. Cl. CPC H02S 30/10; F24J 2002/522; H01L 31/048

(57) ABSTRACT

A solar module having a laminate with two lateral edges, an upper edge and a lower edge. A frame profile extended along a direction of extension is secured on at least one of the lateral and/or upper and/or lower edges of the laminate. The frame profile has in cross-section an outer edge and a U-shaped receiving section with upper and lower U-shaped limbs for receiving one of the laminate edges, and is integrally constructed from a metal strip, which forms the outer edge of the frame profile with an edge plane. The upper U-shaped limb is configured as an upturn of the entire metal strip from the edge plane, and the lower U-shaped limb is configured as metal support sections adjacent in the direction of extension and spaced apart from one another, which metal support sections are bent away from the edge plane as integral parts of the metal strip.

### RELATED APPLICATIONS

The present application is a National Phase entry of PCT Application No. PCT/DE2016/100245, filed May 27, 2016, which claims priority to German Patent Application No. 10 2015 110 908.5, filed Jul. 6, 2015, the disclosures of which are hereby incorporated by reference herein in their entirety.

### FIELD OF THE INVENTION

The invention relates to a solar module which has a solar module laminate with solar module laminate edges, wherein a frame profile is arranged along at least one of the solar module laminate edges. As seen in cross section, the frame profile has a U-shaped receiving portion which encloses the solar module laminate edge.

### BACKGROUND OF THE INVENTION

The strong competition between the manufacturers of solar modules forces them in particular to develop ever more cost-effective solutions for the frame profiles that are used.

Extruded frame profiles are regularly used, which afford lower production costs, the larger the quantities that are produced. A significant cost factor in the case of extruded profiles is the production of the extrusion dies. This forming method inevitably entails degrees of design freedom in only two spatial dimensions for the frame profile produced. A method for producing metal profiles that is much more cost-effective, particularly in the case of smaller quantities, is the forming of metal sheets by rolls, molds and rollers. These production methods can also be carried out as cost-effective inline methods. A rolled profile, for example, is known from the manufacturer Weiser Profile in Ybbsitz, Austria, said rolled profile being shown in figures la and lb. This rolled frame profile extends in an extension direction (E) and has, in cross section, an outer edge (20) and a U-shaped receiving portion (21) with an upper U-shaped limb (22) and a lower U-shaped limb (23) for receiving one of the solar module laminate edges. However, this rolled profile is relatively complicated to produce and thus not cost-effective enough.

### SUMMARY OF THE INVENTION

The present invention is based on the object of providing a solar module having a frame profile, which, while having lower production costs, affords at least the same or greater flexibility with regard to the degrees of design freedom of the frame profile.

This object is achieved by a solar module having the features according to the claims.

The solar module laminate is usually in the form of a glass plate on which electrically interconnected solar cells are arranged in what are known as strings, said solar cells being adhesively covered with a durably weather-resistant plastics film. The glass plate forms the front side of the solar module laminate and the weather-resistant plastics film forms the solar module laminate rear side. The U-shaped receiving portion of the frame construction is usually formed by means of two mutually opposite limbs that are connected by a connecting portion. Said limbs are partially or completely bonded and/or clamped to the solar module laminate by outer edges, such that the frame construction surrounds the solar module laminate as a frame along the outer edges thereof. As a result, the stability and torsional rigidity of the solar module laminate are increased and/or a possible manner of installation is created via the frame construction and/or edge protection for the solar module laminate is ensured.

The layered laminate structure, not belonging to the frame construction, of glass plate, solar cell strings, embedding polymers and weather-resistant plastics film is therefore denoted solar module laminate in the scope of this invention. The combination of the solar module laminate with the frame construction formed from frame profiles is denoted solar module. The difference between the terms solar module and solar module laminate is that, compared with the solar module laminate, the solar module additionally has a frame construction and optionally adhesives and/or clamping means for bonding and clamping the frame construction to the solar module laminate, or other fastening means.

According to the invention, provision is made for the frame profile to be constructed integrally from a metal strip which forms the outer edge of the frame profile with an edge plane, wherein the upper U-shaped limb is formed as a folded edge of the entire metal strip out of the edge plane and the lower U-shaped limb is configured as metal supporting portions that are arranged alongside one another in the extension direction and in a manner spaced apart from one another, said metal supporting portions being bent out of the edge plane of the metal strip as integral parts of the metal strip.

As a result of this structure of the frame profile, it is possible to produce the latter by way of an extremely inexpensive inline method, in which the claimed structure of the frame profile is created for example by rolling, stamping and bending. The lower U-shaped limb is therefore—unlike in an extruded frame profile—not formed in a continuous manner as seen in the extension direction. It is formed by metal supporting portions that are spaced apart from one another and are each bent out of the metal strip.

Preferably, the frame profile is formed structurally only from the metal strip extending in the edge plane and from portions of the metal strip that are bent out of this edge plane, wherein the bent-out portions are integral parts of the metal strip and end at a distance from the edge plane. The feature “formed structurally only” is defined such that the basic structure of the frame profile with its U-shaped receiving portion bearing the solar module laminate consists of the flat metal strip. This definition does not, however, prevent additional structural elements, such as screw-in rivets or metal brackets, for example, from being fastened to the frame profile.

A preferred embodiment of the solar module is distinguished by having a particularly simple structure in that the bent-out portions of the frame profile end without inclusion of cavities. In other words, in the simplest case, the bent-out portions are bent only out of the plane of the metal strip and extend in a rectilinear manner as far as their end portion. Preferably, the bent-out portions are bent substantially perpendicularly out of the plane of the metal strip only once and extend out of the plane of the metal strip as far as their end portion without any further changes in their extension direction.

Preferably, the bent-out portions are formed only as folded upper and/or lower edges of the metal strip along the entire extension direction of the metal strip and as metal supporting portions that are arranged alongside one another in the extension direction and in a manner spaced apart from one another. In this case, a large number of metal supporting portions are provided, which are bent out of the metal strip in a tab-like manner for example after preceding regional stamping, laser cutting or water-jet cutting of the metal strip.

An advantageous embodiment of the solar module is characterized in that at least one of the metal supporting portions is configured to be long enough, as seen in the extension direction, for it to be possible for an installer tasked with installation to fit a hand therein. In this way, a plurality of functionalities of the solar module with the frame profile can be realized without additional components.

In a first variant of the solar module, provision is made for two frame profiles to be fixed together at a corner of two solar module laminate edges by means of a plug connection, wherein one frame profile has, at its end, a tab which is plugged into a tab receptacle in the other frame profile. The tab and the tab receptacle, too, can be produced by simple and thus cost-effective stamping and bending methods.

A second variant of the solar module is characterized in that two frame profiles are fixed together at a corner of two solar module laminate edges by means of a corner bracket or are each pressed into a common corner bracket. This represents a second variant for the corner connection of two frame profiles.

In a third variant of the solar module, two frame profiles are fixed together at a corner of two solar module laminate edges by means of a weld, soldered joint, adhesive bond or screw connection. This represents a cost-effective possibility.

Each of the three abovementioned variants for the corner connection of two frame profiles is preferably configured such that the frame profile extends integrally along the top edge or along the bottom edge and along at least one of the two side edges of the solar module laminate. In other words, in the case of a rectangular solar module laminate, either two mutually abutting solar module laminate edges or three of the total of four solar module laminate edges are framed with an integrally formed frame profile. At the corners, the frame profile has recesses dimensioned such that it is possible to bend the frame profile through substantially 90 degrees. In this way, in contrast to extruded frame profiles, the number of working steps for producing a frame profile surrounding the solar module laminate can be reduced from four to two corner connection processes. As a result, even more cost-effective production of the framed solar module is possible.

Each of the three abovementioned variants for corner connection can advantageously be configured such that the frame profile extends integrally along the top edge, along the bottom edge and along the two side edges of the solar module laminate. The integral frame profile thus encloses all of the edges of the solar module laminate and its starting and end portions are fixed together by means of a corner connection.

### BRIEF DESCRIPTION OF THE DRAWINGS

Further properties and advantages of the invention are explained in connection with the exemplary embodiments shown in the figures and described by way of example in the following text. In the figures:

FIGS. 1a and 1b show a hollow-chamber frame profile known from the prior art, which has been formed from a metal sheet;

FIG. 2 shows a perspective view of a frame profile 2 of a first embodiment of the solar module with its frame profile structure oriented inwardly toward the solar module laminate;

FIG. 3 shows a perspective view of the frame profile 2 from FIG. 2 with the frame profile structure oriented outwardly away from the solar module laminate;

FIG. 4 shows a perspective view of a first variant for the corner connection of two frame profiles 2, 3;

FIG. 5 shows a perspective view of a second variant for the corner connection of two frame profiles 2, 3;

FIG. 6 shows a perspective view of a third variant for the corner connection of two frame profiles 2, 3; and

FIG. 7 shows schematic illustrations of particularly preferred configurations of the solar module with a frame profile 2 that extends integrally along two, three or four solar module laminate edges.

### DETAILED DESCRIPTION

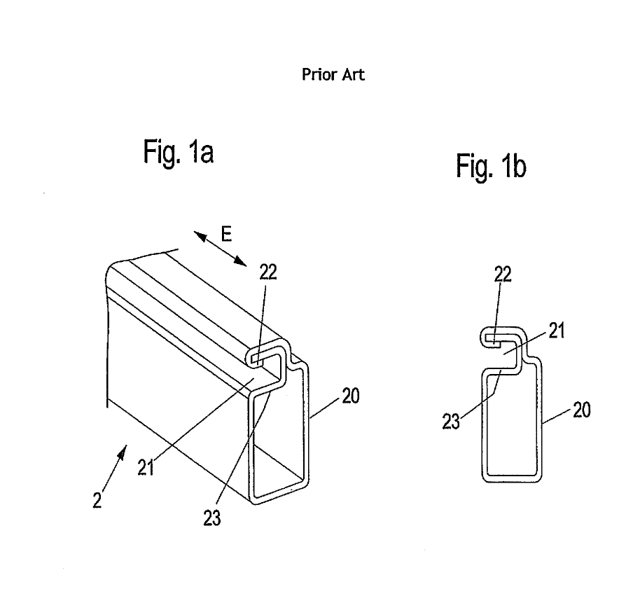

FIGS. 1a and 1b show a hollow-chamber frame profile known from the prior art, which has been formed from a metal sheet. This solar module frame profile has already been described in the introduction. Reference is made to this description here.

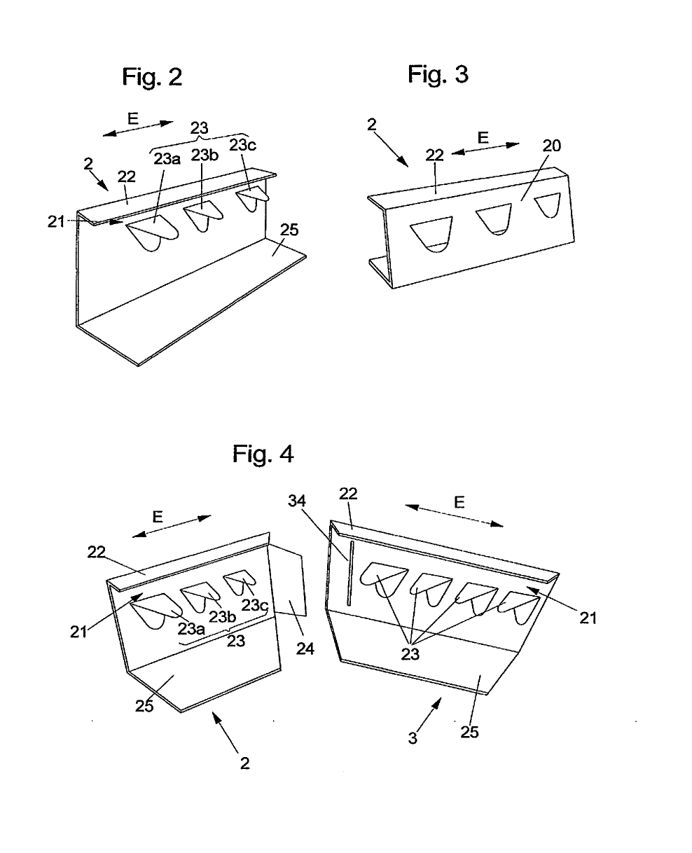

FIG. 2 shows a perspective view of a frame profile 2 of a first embodiment of the solar module with its frame profile structure oriented inwardly toward the solar module laminate. The frame profile 2 extends in an extension direction E and is formed from a simple metal sheet. The upper edge of the metal sheet is folded through substantially 90 degrees out of the plane of the metal sheet, as seen in the extension direction E, and forms an upper U-shaped limb. The lower edge of the metal sheet is likewise folded substantially parallel to the upper U-shaped limb 22 in the extension direction E and forms the lower limb 25. Between the upper U-shaped limb 22 and the lower limb 25, the metal sheet of the frame profile 2 extends in the plane of the metal sheet. Out of this plane in the extension direction E, alongside one another but spaced apart from one another, three tab-like metal supporting portions 23a, 23b, 23c have been bent out of the plane of the metal sheet through substantially 90 degrees substantially parallel to the upper U-shaped limb 22. These three metal supporting portions 23a, 23b, 23c form, with further metal supporting portions that are not shown, the lower U-shaped limb 23 of a U-shaped receiving portion 21, which engages around the solar module laminate 1 (indicated only by dashed lines here for the sake of clarity) with one of its solar module laminate edges.

FIG. 3 shows a perspective view of the frame profile 2 from FIG. 2 with the frame profile structure oriented outwardly away from the solar module laminate 1. The regular opening behavior, caused by the regularly spaced-apart arrangement of metal supporting portions 23a, 23b, 23c, of the frame profile outer edge 20 promotes in particular the rear ventilation of the solar module laminate plate. Furthermore, the openings can also be configured regionally in a larger manner such that mechanical engagement for transport and installation of the solar module is ensured.

FIG. 4 shows a perspective view of a first variant for the corner connection of two frame profiles 2, 3. The two frame profiles 2, 3 are formed in the extension direction E, as shown in FIGS. 2 and 3.

Formed at the end of one frame profile 2 is a tab 24, which extends from the upper U-shaped limb 22 to the lower limb 25 and has been bent out of the plane of the outer edge 20. In a manner corresponding to the tab 24, a tab receptacle 34 in the form of a slit is located in the other frame profile 3, said tab receptacle 34 extending from the upper U-shaped limb 22 to the lower limb 25. When the two frame profiles are joined together, the tab 24 is plugged into the tab receptacle 34 and can be additionally fixed by fastening means such as rivets, screws or adhesives and solders, for example.

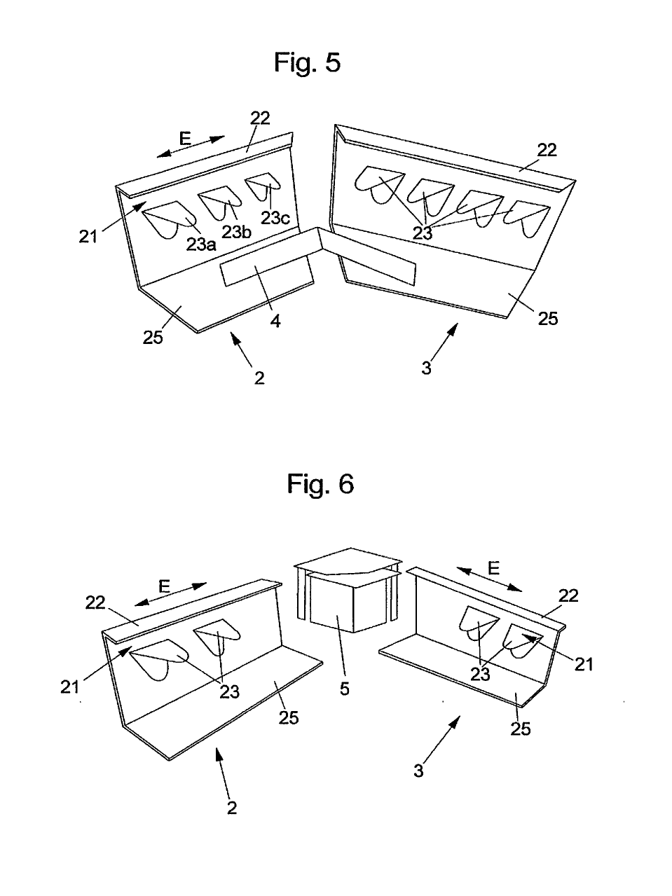

FIG. 5 shows a perspective view of a second variant for the corner connection of two frame profiles 2, 3. In contrast to the first variant shown in FIG. 4, in this case an additional component in the form of a corner connector 4 is provided. The corner connector 4 is configured as an angle plate with two limbs and is fastened with in each case one of its limbs to the frame profiles 2, 3 to be joined together. To this end, too, all types of form- and/or force-fitting connecting means are suitable.

FIG. 6 shows a perspective view of a third variant for the corner connection of two frame profiles 2, 3. Here too, as in the second variant in FIG. 5, a corner connector 5 is used. However, this corner connector 5 is of more complex construction compared with the variant in FIG. 5. It is in this case a corner connector 5 known from the prior art, which allows the end portions of the two frame profiles 2, 3 to be pressed into the corner connector 5.

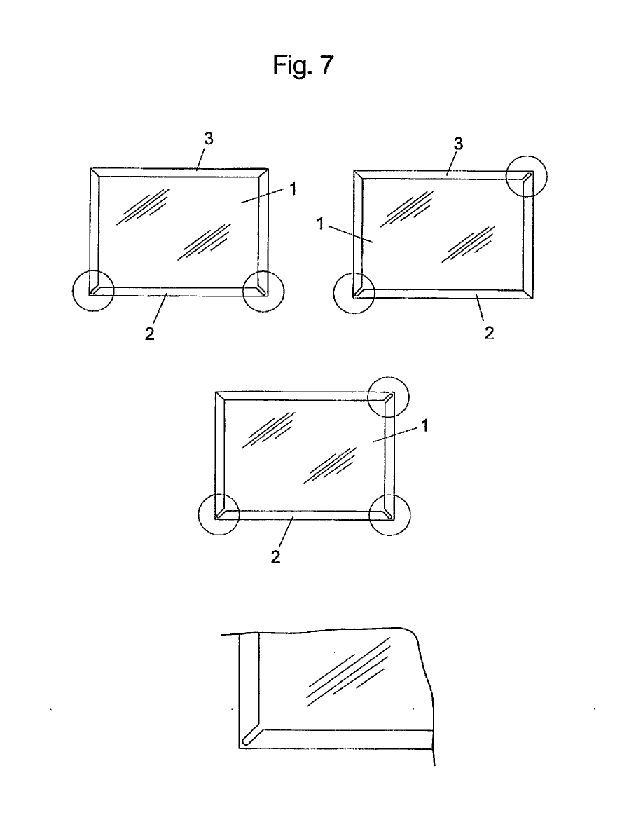

FIG. 7 shows a schematic illustration of particularly preferred configurations of the solar module with a frame profile 2 which extends integrally along two, three or four solar module laminate edges. The corner regions, emphasized by circles, of the frame profile 2 are illustrated in an enlarged manner. It is apparent from the enlarged illustration that the frame profile 2 is formed integrally in these corner regions. The angle is realized by corresponding bending of the frame profile 2. The frame profile 2 is provided, in these corner regions, with recesses in the upper U-shaped limb 22 and the lower limb 25, such that when the frame profile 2 is bent at right angles, the corresponding limbs do not tilt into one another.

### LIST OF REFERENCE SIGNS

1 Solar module laminate
2 Frame profile

20 Outer edge

21 U-shaped receiving portion

22 Upper U-shaped limb

23a, 23b, 23c Metal supporting portions

23 Lower U-shaped limb

24 Tab

25 Lower limb
3 Frame profile

34 Tab receptacle
4 Corner bracket
5 Corner bracket

1. A solar module having a solar module laminate which has two side edges, a top edge and a bottom edge as solar module laminate edges, wherein a frame profile that extends in an extension direction is fixed to at least one of the side edges and/or to the top edge and/or to the bottom edge of the solar module laminate, said frame profile having, in cross section, an outer edge and a U-shaped receiving portion with an upper U-shaped limb and a lower U-shaped limb for receiving one of the solar module laminate edges,
wherein the frame profile is constructed integrally from a metal strip which forms the outer edge of the frame profile with an edge plane, wherein the upper U-shaped limb is formed as a folded edge of the entire metal strip out of the edge plane and the lower U-shaped limb is configured as metal supporting portions that are arranged alongside one another in the extension direction and in a manner spaced apart from one another, said metal supporting portions being bent out of the edge plane of the metal strip as integral parts of the metal strip.

2. The solar module as claimed in claim 1, wherein the frame profile is formed structurally only from the metal strip extending in the edge plane and from portions of the metal strip that are bent out of this edge plane, wherein the bent-out portions are integral parts of the metal strip and end at a distance from the edge plane.

3. The solar module as claimed in claim 2, wherein the bent-out portions end without inclusion of cavities.

4. The solar module as claimed in claim 2, wherein the bent-out portions are formed only as folded upper and/or lower edges of the metal strip along the entire extension direction of the metal strip and as metal supporting portions that are arranged alongside one another in the extension direction and in a manner spaced apart from one another.

5. The solar module as claimed in claim 1, wherein at least one of the metal supporting portions is configured to be long enough, as seen in the extension direction, for it to be possible for an installer tasked with installation to fit a hand therein.

6. The solar module as claimed in claim 1, wherein two frame profiles are fixed together at a corner of two solar module laminate edges by means of a plug connection, wherein one frame profile has, at its end, a tab which is pulgged into a tab receptacle in the other frame profile.

7. The solar module as claimed in claim 1, wherein two frame profiles are fixed together at a corner of two solar module laminate edges by means of a corner bracket or are each pressed into a common corner bracket.

8. The solar module as claimed in claim 1, wherein two frame profiles are fixed together at a corner of two solar module laminate edges by means of a weld, soldered joint, adhesive bond or screw connection.

9. The solar module as claimed in claim 1, wherein the frame profile extends integrally along the top edge or along the bottom edge and along at least one of the two side edges of the solar module laminate.

10. The solar module as claimed in claim 1, wherein the frame profile extends integrally along the top edge, along the bottom edge and along the two side edges of the solar module laminate.
